(19) United States
(12) Patent Application Publication
(10) Pub. No.: US 2009/0123878 A1
(43) Pub. Date: May 14, 2009

(54) PATTERNING METHOD

(76) Inventors: Seiro MIYOSHI, Kanagawa-ken (JP); Eishi Shiobara, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/256,240

(22) Filed: Oct. 22, 2008

(30) Foreign Application Priority Data
Oct. 23, 2007 (JP) 2007-275497

(51) Int. Cl. G03F 7/20

(52) U.S. Cl. 430/325

(57) ABSTRACT

A patterning method includes: forming a first film on a workpiece substrate; forming a second film on the first film, the second film being a silicon film having a lower optical absorption coefficient with respect to EUV (extreme ultraviolet) light than the first film; forming a resist film on the second film; selectively irradiating the resist film with the EUV light; and developing the resist film.

### CROSS-REFERENCE TO RELATED APPLICATIONS

This application is based upon and claims the benefit of priority from the prior Japanese Patent Application No. 2007-275497, filed on Oct. 23, 2007; the entire contents of which are incorporated herein by reference.

### BACKGROUND OF THE INVENTION

1. Field of the Invention

This invention relates to a patterning method applied to a lithography process based on EUV (extreme ultraviolet) light.

2. Background Art

With the recent demand for high-density semiconductor devices, studies have been made to use EUV light having a wavelength of 13.5 nm as a light source for lithography, rather than ArF light having a wavelength of 193 mm which is now mainly used. However, because EUV light has high energy, it generates secondary electrons when absorbed in the film. The secondary electrons act on the resist film as stray light, which may deteriorate the resist pattern accuracy. Furthermore, the film may be damaged by irradiation with EUV light itself. Here, it is known that the optical absorption coefficient of a material with respect to EUV light depends on the kind of its constituent elements rather than the molecular structure of the material (see, e.g., “Proceedings of SPIE”, vol. 3997 (2000) p. 588-599).

### SUMMARY OF THE INVENTION

According to an aspect of the invention, there is provided a patterning method including: forming a first film on a workpiece substrate; forming a second film on the first film, the second film being a silicon film having a lower optical absorption coefficient with respect to EUV (extreme ultraviolet) light than the first film; forming a resist film on the second film; selectively irradiating the resist film with the EUV light; and developing the resist film.

According to an aspect of the invention, there is provided a patterning method including: forming a first film on a workpiece substrate; forming a second film on the first film, the second film having a lower optical absorption coefficient with respect to EUV (extreme ultraviolet) light than the first film; forming a third film on the second film, the third film having a higher optical absorption coefficient with respect to the EUV light than the second film; forming a resist film immediately on the third film; selectively irradiating the resist film with the EUV light; and developing the resist film.

### BRIEF DESCRIPTION OF THE DRAWINGS

FIGS. 1A to 1E are schematic views for illustrating a patterning method according to a first embodiment of the invention;

FIGS. 2A and 2B are schematic views for illustrating a patterning method according to a second embodiment of the invention;

FIG. 3 is a schematic view showing the skirt shape at the basal portion of the resist film; and

FIG. 4 is a flow chart illustrating part of a process for manufacturing a semiconductor device according to this embodiment.

### DETAILED DESCRIPTION OF THE INVENTION

Embodiments of the invention will now be described with reference to the drawings.

### First Embodiment

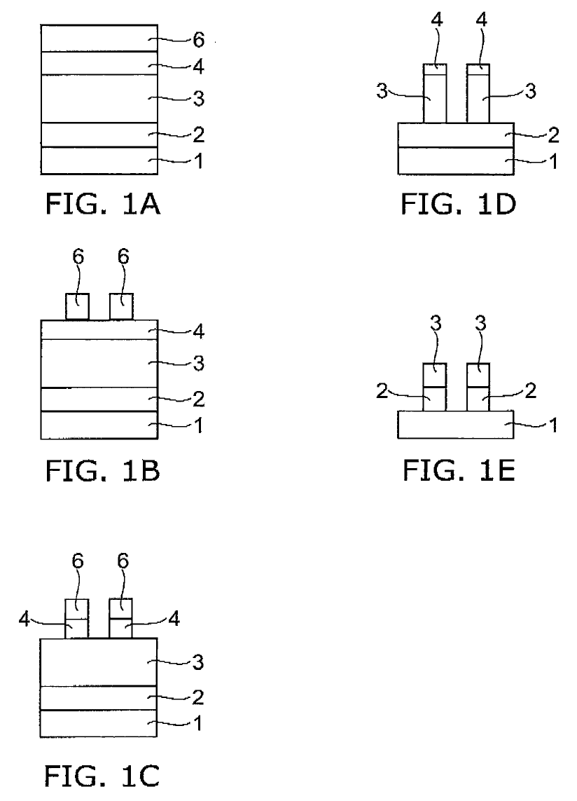

FIG. 1 is a schematic view for illustrating a patterning method according to a first embodiment of the invention, showing the cross section of the substrate and various films laminated thereon. In the following embodiments, a “workpiece substrate”, or a target to be processed, is Illustratively a substrate 1 with a subject film 2 formed thereon. However, the embodiments encompass the case where the “workpiece substrate” is the substrate 1 alone.

First, as shown in FIG. 1A, on a substrate 1 illustratively made of silicon, a subject film 2, a first film 3, and a second film 4 are sequentially formed. For example, the subject film 2 has a thickness of 200 nm, the first film 3 has a thickness of 300 nm, and the second film 4 has a thickness of 30 nm.

The subject film 2 is illustratively a silicon oxide film, a silicon nitride film, or other insulating films, a conductor film, or a semiconductor film.

The first film 3 has a higher optical absorption coefficient with respect to EUV light around a wavelength of 13.5 nm than the second film 4. That is, the second film 4 has a lower optical absorption coefficient with respect to EUV light around a wavelength of 13.5 nm than the first film 3.

The optical absorption coefficient of a material with respect to EUV light around a wavelength of 13.5 nm depends on the kind of its constituent elements rather than the molecular structure of the material (see, e.g., “Proceedings of SPIE”, vol. 3997 (2000) p. 588-599). The magnitude relation of the optical absorption coefficient can be expressed by the following inequality: Si (silicon)<H (hydrogen)<C (carbon)<N (nitrogen)<O (oxygen)<F (fluorine)<Al (aluminum).

From this viewpoint, the second film 4 can illustratively be a polycrystalline silicon film, and the first film 3 can illustratively be an organic film primarily containing C (carbon).

The second film 4 is not limited to a polycrystalline silicon film, but other silicon films such as an amorphous silicon film can also be used. Furthermore, the second film 4 can be other than silicon films as long as it has a lower optical absorption coefficient with respect to EUV light than the first film 3. However, among the materials often used in normal semiconductor processes, silicon is one of the materials having the lowest optical absorption coefficient with respect to EUV light. Furthermore, silicon films are superior in easiness and controllability of film formation and processing, and also cost-effective. Hence, the second film 4 is preferably a silicon film such as a polycrystalline silicon film and an amorphous silicon film.

Besides organic films, the first film 3 can also be a film containing at least one of fluorine, oxygen, and aluminum.

Furthermore, preferably, the first film 3 is thicker than the second film 4, that is, the second film 4 is thinner than the first film 3, so that the amount of EUV light absorbed in the first film 3 is larger and that the amount of EUV light absorbed in the second film 4 is smaller.

After the second film 4 is formed, a resist is applied onto the second film 4 illustratively by spincoating, and baked (heat treated) to form a resist film 6 having a thickness of 100 nm. The resist film 6 is, illustratively, a positive resist made of a resin-based material containing at least one element of H (hydrogen), C (carbon), O (oxygen), and N (nitrogen), in which the portion exposed to EUV light around a wavelength of 13.5 nm is dissolved in a developer. It is understood that the resist film 6 is not limited thereto, but can also be a negative resist in which the portion not exposed to EUV light is dissolved in a developer.

Next, an EUV exposure apparatus with numerical aperture NA=0.25 is used to selectively irradiate the resist film 6 with EUV light around a wavelength of 13.5 nm for exposure from the frontside through a photomask, not shown, and then the resist film 6 is baked (heat treated). Subsequently, the resist film 6 is developed, illustratively, with a 2.38% aqueous solution of tetramethylammonium hydroxide (TMAH) and rinsed with pure water. Thus, the resist film 6 is processed, illustratively, into a line-and-space pattern having a line width of 40 nm and a period of 80 nm as shown in FIG. 1B.

According to this embodiment, during the exposure with EUV light described above, absorption of EUV light in the second film 4 immediately below the resist film 6 is small. Thus, this embodiment can prevent generation of secondary electrons acting on the resist film 6 as stray light, and the resist film 6 is patterned into a desired favorable shape having a rectangular cross section as shown in FIG. 1B.

Furthermore, the first film 3 having a higher optical absorption coefficient with respect to EUV light than the second film 4 is formed immediately below the second film 4, and allows most of the EUV light to be absorbed in the first film 3. Thus, its incidence on the subject film 2 and the substrate 1 can be prevented, and no damage is caused thereto.

If the second film 4 has an extremely large thickness, the amount of optical absorption increases even if the second film 4 is made of a material having a low optical absorption coefficient with respect to EUV light. Thus, the second film 4 is preferably thin, but needs to have a thickness large enough to prevent electrons generated in the underlying first film 3 from reaching the resist film 6.

The pattern formed in the resist film 6 is successively transferred to the underlying layers. More specifically, the resist film 6 is used as a mask to etch the second film 4 as shown in FIG. 1C, the second film 4 is used as a mask to etch the first film 3 as shown in FIG. 1D, and the first film 3 is used as a mask to etch the subject film 2 as shown in FIG. 1E. According to this embodiment, as described above, the resist film 6 can be accurately processed into a desired pattern. Hence, the processing accuracy of the subject film 2, that is, the final target to be processed, can also be enhanced, consequently contributing to improved quality of products.

### Second Embodiment

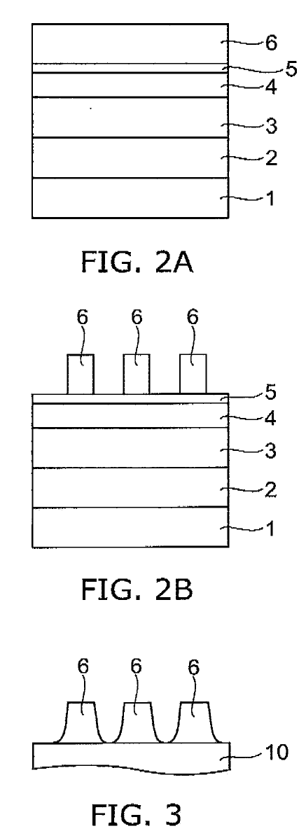

FIG. 2 is a schematic view for illustrating a patterning method according to a second embodiment of the invention. Components similar to those in the first embodiment described above with reference to FIG. 1 are labeled with like reference numerals.

In exposure with EUV light using a positive resist, as shown in FIG. 3, the basal portion of the resist film 6 tends to be processed into a skirt shape. This is attributed to the fact that the resist film 6 reacts with EUV light and becomes soluble in a developer not only in the portion directly irradiated with EUV light, but also in the portion to which EUV light is diffused approximately 1 to 2 nm from the portion irradiated with EUV light. That is, in the vicinity of the boundary between the resist film 6 and the underlying layer 10, the resist film 6 receives no diffusion of EUV light from below, and is prone to underexposure.

Thus, in the second embodiment of the invention, as shown in FIG. 2A, a third film 5 having a higher optical absorption coefficient with respect to EUV light than the second film 4 is formed between the resist film 6 and the second film 4, immediately below the resist film 6.

The third film 5 can be made of a material having an optical absorption coefficient comparable to that of the first film 3, and can illustratively be an organic film primarily containing C (carbon). However, if the third film 5 has an extremely large thickness, a large number of secondary electrons are generated in the third film 5 upon irradiation with EUV light and act as stray light on the resist film 6 immediately thereabove. Thus, the processing accuracy of the resist film 6 may be deteriorated.

Hence, the thickness of the third film 5 needs to be less than 1 to 2 nm, which is the minimum thickness required to diffuse the EUV light absorbed by the third film 5 into the bottom (the vicinity of the interface with the third film 5) of the resist film 6. However, in accordance with different materials and exposure conditions of the films, and in view of the process variation and the like, the maximum thickness up to 5 nm is allowable.

Also in this embodiment, an EUV exposure apparatus with numerical aperture NA=0.25 is used to selectively irradiate the resist film 6 with EUV light around a wavelength of 13.5 nm for exposure from the frontside through a photomask, not shown, and then the resist film 6 is baked (heat treated). Subsequently, the resist film 6 is developed, illustratively, with a 2.38% aqueous solution of tetramethylammonium hydroxide (TMAH) and rinsed with pure water. Thus, the resist film 6 is processed, illustratively, into a line-and-space pattern having a line width of 40 nm and a period of 80 nm as shown in FIG. 2B.

Furthermore, also in this embodiment, during the exposure with EUV light described above, absorption of EUV light in the second film 4 below the resist film 6 is small. Thus, this embodiment can prevent generation of secondary electrons acting on the resist film 6 as stray light, and the resist film 6 is patterned into a desired favorable shape having a rectangular cross section as shown in FIG. 2B.

Furthermore, the first film 3 having a higher optical absorption coefficient with respect to EUV light than the second film 4 is formed immediately below the second film 4, and allows most of the EUV light to be absorbed in the first film 3. Thus, Its incidence on the subject film 2 and the substrate 1 can be prevented, and no damage is caused thereto.

Moreover, in this embodiment, immediately below the resist film 6, a third film 5 having a higher optical absorption coefficient with respect to EUV light than the second film 4 is formed with the thickness designed in consideration of the diffusion distance of EUV light required to cause the reaction of the resist film 6. Hence, EUV light applied to the third film 5 is diffused toward the bottom of the resist film 6 immediately thereabove and can avoid incomplete reaction at the bottom of the resist film 6. Consequently, the resist film 6 can be processed into a desired favorable rectangular pattern.

Subsequently, like the first embodiment, the pattern formed in the resist film 6 is successively transferred to the underlying layers.

### Third Embodiment

Next, as a third embodiment of the invention, a method for manufacturing a semiconductor device based on the above patterning method is described. That is, the above patterning method according to the embodiments of the invention can be applied to the processing of interconnects and insulating films to manufacture various semiconductor devices.

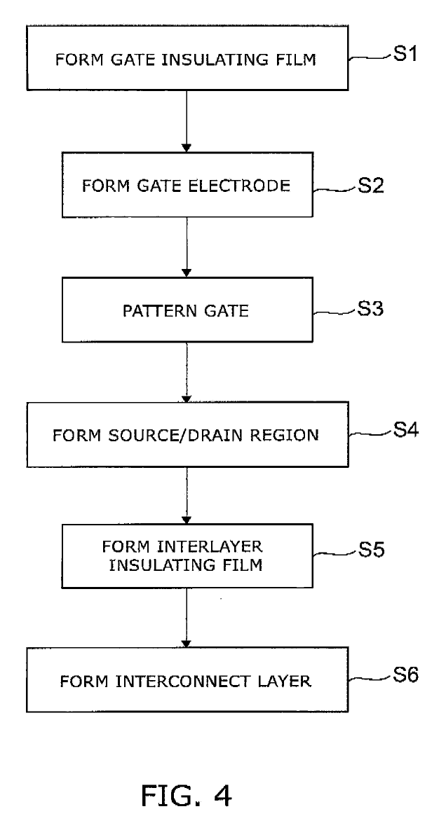

FIG. 4 is a flow chart illustrating part of a process for manufacturing a semiconductor device according to this embodiment. This figure illustrates a process for manufacturing a MOSFET (metal-oxide-semiconductor field effect transistor) taken as an example of the semiconductor device.

In manufacturing a MOSFET, first, a gate insulating film is formed illustratively on a silicon substrate or a silicon layer (hereinafter collectively referred to as a wafer) (step S1). Then, a conductor layer to serve as a gate electrode is formed on the gate insulating film (step S2). Subsequently, a prescribed mask is formed, and the conductor layer and the gate insulating film are patterned (step S3). In this step of gate patterning, the patterning method of the embodiments of the invention can be used.

More specifically, on the conductor layer to serve as a gate electrode, the first film 3, the second film 4, the third film 5 as needed, and the resist film 6 described above are formed and subjected to exposure, baking, development, cleaning, drying and the like to form a desired resist pattern. This resist pattern is used as a mask to etch the gate electrode and the gate insulating film.

Subsequently, the patterned gate is used as a mask to dope the wafer with impurities, thereby forming a source/drain region (step S4). Then, an interlayer insulating film is formed on the wafer (step S5), and an interconnect layer is further formed thereon (step S6). Thus, the main part of the MOSFET is completed. Here, the patterning method of the embodiments of the invention can be used also in the step of forming a via in the interlayer insulating film for contact between the interconnect layer and the source/drain region, and in the step of patterning the interconnect layer. Thus, the patterns being processed can be accurately processed into a desired shape, consequently contributing to improved quality of the semiconductor device.

The embodiments of the invention have been described with reference to examples. However, the invention is not limited thereto, but can be variously modified within the spirit of the invention.

1. A patterning method comprising:
forming a first film on a workpiece substrate;
forming a second film on the first film, the second film being a silicon film having a lower optical absorption coefficient with respect to EUV (extreme ultraviolet) light than the first film;
forming a resist film on the second film;
selectively irradiating the resist film with the EUV light; and
developing the resist film.

2. The method according to claim 1, wherein the first film is an organic film.

3. The method according to claim 1, wherein the EUV light has a wavelength around 13.5 nm.

4. The method according to claim 1, wherein the workpiece substrate includes a silicon substrate and a subject film formed on the silicon substrate.

5. The method according to claim 1, wherein the first film contains at least one of fluorine, oxygen, and aluminum.

6. The method according to claim 1, wherein the first film is thicker than the second film.

7. The method according to claim 1, wherein the resist film is made of a resin-based material containing at least one of hydrogen, carbon, oxygen, and nitrogen.

8. A patterning method comprising:
forming a first film on a workpiece substrate;
forming a second film on the first film, the second film having a lower optical absorption coefficient with respect to EUV (extreme ultraviolet) light than the first film;
forming a third film on the second film, the third film having a higher optical absorption coefficient with respect to the EUV light than the second film;
forming a resist film immediately on the third film;
selectively irradiating the resist film with the EUV light; and
developing the resist film.

9. The method according to claim 8, wherein the second film is a silicon film.

10. The method according to claim 8, wherein the first film is an organic film.

11. The method according to claim 8, wherein the EUV light has a wavelength around 13.5 nm.

12. The method according to claim 8, wherein the workpiece substrate includes a silicon substrate and a subject film formed on the silicon substrate.

13. The method according to claim 8, wherein the first film contains at least one of fluorine, oxygen, and aluminum.

14. The method according to claim 8, wherein the first film is thicker than the second film.

15. The method according to claim 8, wherein the resist film is made of a resin-based material containing at least one of hydrogen, carbon, oxygen, and nitrogen.

16. The method according to claim 8, wherein the optical absorption coefficient of the third film with respect to the EUV light is comparable to that of the first film.

17. The method according to claim 8, wherein the third film is an organic film.

18. The patterning method according to claim 8, wherein the third film is thinner than the first film.

19. The method according to claim 18, wherein the third film is thinner than the second film.

20. The method according to claim 8, wherein the third film has a thickness of 5 nm or less.
